(19) United States
(12) Patent Application Publication
(10) Pub. No.: US 2009/0308446 A1
(43) Pub. Date: Dec. 17, 2009

(54) BACKSIDE ELECTRODE LAYER AND FABRICATING METHOD THEREOF

(75) Inventors: Ching-Hsi Lin, Hsinchu City (TW); Shih-Peng Hsu, Hsinchu County (TW); Chien-Rong Huang, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: INDUSTRIAL TECHNOLOGY RESEARCH INSTITUTE, Hsinchu (TW)

(21) Appl. No.: 12/191,317

(22) Filed: Aug. 14, 2008

(30) Foreign Application Priority Data
Jun. 11, 2008 (TW) 97121769

(51) Int. Cl. H01L 31/00; H01L 21/00

(52) U.S. Cl. 136/256; 438/73

(57) ABSTRACT

A backside electrode layer and a fabricating method thereof are applicable for fabricating a solar cell. The backside electrode layer includes a first electrode layer and a second electrode layer. The first electrode layer is formed on a substrate and has a thickness smaller than 15 μm. The second electrode layer having patterns is formed on the first electrode layer. The first and second electrode layers are fabricated by a cofiring process. As the thickness of the first electrode layer is decreased and the second electrode layer is not a full coverage layer, the material usage of each electrode layer is reduced and the fabrication cost thereof is leveled down. Besides, a thinner electrode layer may avoid warp after the cofiring process.

### CROSS-REFERENCE TO RELATED APPLICATION

This application claims the priority benefit of Taiwan application serial no. 97121769, filed on Jun. 11, 2008. The entirety of the above-mentioned patent application is hereby incorporated by reference herein and made a part of this specification.

### BACKGROUND OF THE INVENTION

1. Field of the Invention

The present invention generally relates to a photovoltaic device and a fabricating method thereof, in particular, to a backside electrode layer and a fabricating method thereof.

2. Description of Related Art

As a clean and renewable energy source, solar energy has always been considered an ideal solution of the pollution and energy shortage problems of the petrochemical energy source. Since the solar cell can directly convert solar energy into electric energy, it has become an important research topic at present.

The solar cell is a photovoltaic device for energy conversion. Basically, a solar cell includes a substrate, a P-N diode, an anti-reflection layer, and two metal electrodes. Briefly speaking, the working principle of the solar cell lies in that, upon being irradiated by the sunlight, the P-N diode converts the light energy into the electric energy, and then the electric energy is output by the positive and negative electrodes.

Generally, the electrodes in the solar cell module are respectively disposed on a non-irradiated surface and an irradiated surface, which are provided for connecting to external circuits. The non-irradiated surface is regarded as a backside, and the irradiated surface is regarded as a front side. The backside electrode is usually formed with a metal layer on the surface, for enhancing the collection of carriers and recycling unabsorbed photons. Besides the function of effectively collecting carriers, the frontside electrode is further employed to reduce the proportion of incident lights shaded by metal wires. Therefore, the frontside electrode is usually designed to have special patterns, for example, a row of finger-shaped metal electrodes extends from a bar-shaped metal electrode. In addition, the backside electrode is usually fabricated in a full coverage manner.

With the development of technology, the solar cell becomes thinner and thinner. Under such a trend, the material cost may be reduced, and the performance of the solar cell may be improved as well. Accordingly, the fabrication of a conductive electrode has become an important research topic due to its impacts on the working efficiency and cost of the cell.

Generally, the fabrication manner of an electrode layer of the solar cell mainly includes vacuum sputtering of a metal thin film, evaporation of a metal thin film, and screen printing of a metal conductive adhesive, in which the cost of the sputtering process and evaporation is rather expensive. When an electrode layer is fabricated through a conventional screen printing process, a high-temperature cofiring process is adopted to fire the metal conductive adhesive into a cured electrode layer. However, during the cooling process after cofiring, due to different thermal expansions of the substrate and the electrode layer, the resulted substrate may warp. The warped solar cell substrate may be easily ruptured in the subsequent packaging process, thereby affecting the production yield a lot. A thinner electrode layer may be fabricated to reduce the stress generated due to the difference of the thermal expansions, thereby eliminating the warping problem. However, during the high-temperature cofiring process, metal particles contained in the metal conductive adhesive of the thin electrode layer may be merged into larger particles and further aggregated into balls. Such agglomeration phenomenon may result in solar cell ruptured in the subsequent packaging process.

A thin metal layer has various applications when being adopted to fabricate an electrode for a solar cell. Particularly, the thin metal layer may be combined with an insulating layer such as SiO₂ or SiNₓ to form an electrode system with a passivation function. In U.S. Pat. No. 6,147,297, U.S. Pat. No. 3,888,698, U.S. Pat. No. 3,982,964, U.S. Pat. No. 4,395,583, U.S. Pat. No. 5,011,565, and U.S. Pat. No. 4,626,613, a thin metal layer is combined with an insulating layer such as SiO₂ or SiNₓ to form an electrode system with a passivation function for a silicon substrate. The insulating layer consumes dangling bonds on the surface of the silicon substrate to achieve the passivation effect. Furthermore, the insulating layer is used to accumulate charges to produce an electric field. In a net direction of the electric field, the minority carriers in a p-type silicon substrate are prevented from being accumulated near the surface of the substrate, thereby reducing the probability that the electrons and holes are recombined on the rear surface.

In U.S. Pat. No. 5,661,041 and U.S. Pat. No. 4,737,197, a method of fabricating a backside electrode for a solar cell has been disclosed. In the method of fabricating a backside electrode for a commercial silicon solar cell, a layer of aluminum conductive adhesive with a thickness of about 25-30 μm is screen printed on a substrate. The content of the aluminum is about 60-80 wt %, and the glass powder is about 2-5 wt %. As the Al—Si eutectic temperature is only 577° C., the Al as a Group III element may be easily diffused into Si as a Group IV element. Therefore, after a cofiring process performed on the aluminum conductive adhesive together with a frontside electrode layer, a p⁺-silicon layer with a doping concentration greater than 10¹⁸ cm⁻³ is easily generated. The p⁺-silicon layer and a p-type silicon substrate (with a doping concentration of about 10¹⁶ cm⁻³) together form a high-low p⁺-p junction. The p⁺-p junction may generate a back surface field (BSF), so as to effectively prevent the minority carriers, i.e., electrons, in the p-type silicon substrate from being accumulated near the surface. Therefore, the probability that electrons and holes are recombined on the rear surface is reduced, and the performance of the solar cell is enhanced. In the above method, the BSF is generated after cofiring the aluminum conductive adhesive formed through screen printing, so as to achieve the passiviation effect, which is rather simple and applicable for mass production, but the substrate together with the electrode layer may easily warp in practice due to its improper thickness, and thus the rupture probability is increased.

In view of the above prior art, the thin metal layer has been widely applied in various different applications in terms of the solar cell electrode. Generally, a thin metal layer formed by sputtering or evaporation is time-consuming and expensive, and a thin metal layer formed through screen printing cannot overcome poor-quality problems such as agglomeration and warping.

### SUMMARY OF THE INVENTION

Accordingly, the present invention is directed to a backside electrode layer and a fabricating method thereof, so as to reduce the fabrication cost.

The present invention is directed to a backside electrode layer and a fabricating method thereof, so as to solve a warping problem.

A backside electrode layer is provided, which includes a first electrode layer and a second electrode layer. The first electrode layer is formed on a substrate and has a thickness smaller than 15 μm. The second electrode layer having patterns is formed on the first electrode layer.

A fabricating method of a backside electrode layer is further provided, which includes steps of providing a substrate, screen printing a first electrode layer with a thickness smaller than 15 μm on the substrate, screen printing a second electrode layer having patterns on the first electrode layer, and cofiring the first electrode layer and the second electrode layer.

In the backside electrode layer and the fabricating method thereof provided by the present invention, a first electrode layer with a thickness smaller than 15 μm and a second electrode layer having patterns are formed to reduce the used material and to lower the fabrication cost of the electrode layer. Moreover, the first electrode layer with a thickness smaller than 15 μm remains flat after the firing process, so that the warping problem of the electrode layer is solved.

In order to make the aforementioned and other objectives, features, and advantages of the present invention comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view of a structure of a solar cell according to an embodiment of the present invention.

FIG. 2 is a top view of a backside electrode of a solar cell according to an embodiment of the present invention.

FIG. 3 is a flow chart of a fabrication process of a backside electrode layer according to an embodiment of the present invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

In the following embodiments of the present invention, the backside electrode layer and the fabricating method thereof provided by the present invention are illustrated by, for example, being applied to fabricate a solar cell, but the present invention is not limited here. Of course, in addition to the solar cell, the present invention may also be applicable for various devices, which will not be particularly limited herein.

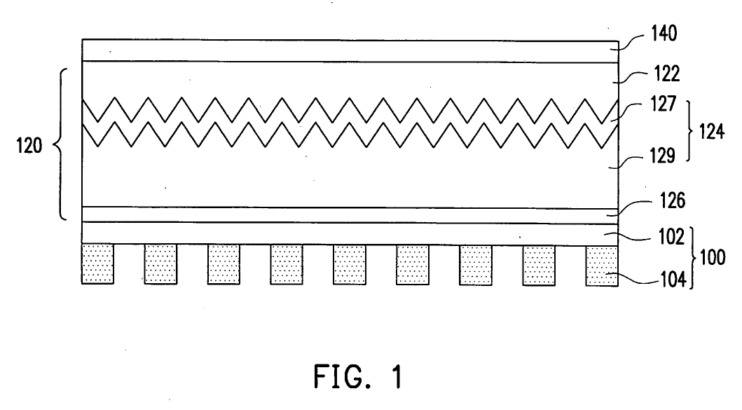

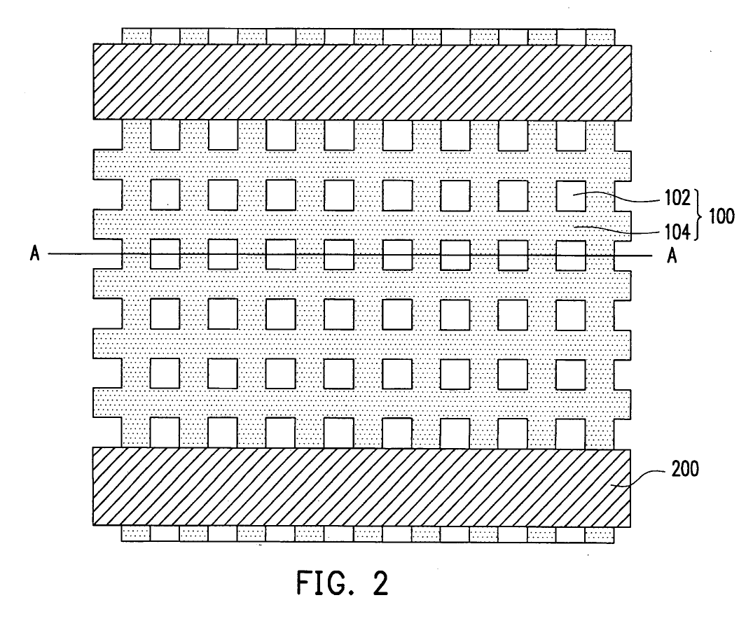

FIG. 1 is a cross-sectional view of a structure of a solar cell according to an embodiment of the present invention. FIG. 2 is a top view of a backside of a solar cell. FIG. 1 is a cross-sectional view taken along the line A-A in FIG. 2.

Referring to FIG. 1, the solar cell mainly includes a backside electrode layer 100, a solar cell substrate 120, and a frontside electrode layer 140. The solar cell substrate 120 is disposed between the backside electrode layer 100 and the frontside electrode layer 140. That is, the backside electrode layer 100 and the frontside electrode layer 140 are respectively located on two opposite surfaces of the solar cell substrate 120.

The backside electrode layer 100 includes a first electrode layer 102 and a second electrode layer 104. The first electrode layer 102 is connected to the solar cell substrate 120.

The first electrode layer 102 is, for example, formed by firing an aluminum conductive adhesive. The aluminum conductive adhesive is, for example, a mixture formed by mixing organic substances such as an aluminum adhesive, a bonding agent, a dispersant, a modifier, and a solvent. For instance, the aluminum adhesive is a commercial aluminum adhesive with a content of about 20-30 wt %, the bonding agent is ethyl cellulose with a content of about 5-15 wt %, the dispersant is polyvinyl butyral resin with a content of about 5-15 wt %, the modifier is palmitic acid with a content of about 0.005-0.015 wt %, and the solvent is α-terpineol with a content of about 20-50 wt %. Therefore, with the above aluminum conductive adhesive, a thin and uniform first electrode layer 102 can be fabricated, so as to effectively avoid the agglomeration phenomenon and to maintain the flatness of the electrode layer after the firing process. In this embodiment, the thickness of the first electrode layer 102 is, for example, 15 μm, and preferably, 10 μm.

The second electrode layer 104 having patterns is formed on the first electrode layer 102. The patterns on the second electrode layer 104 are, for example, grid, hexagonal grid, triangular grid, or other non-full coverage patterns. The second electrode layer 104 is, for example, made of a conventional Ag—Al adhesive.

As shown in FIG. 2, a bus line 200 is further disposed on the backside electrode layer 100. The bus line 200 is made of, for example, an Ag—Al adhesive. The material of the bus line 200 may be identical to or different from that of the second electrode layer 104.

The solar cell substrate 120 is formed by, for example, a first anti-reflection layer 122, a photoelectric conversion layer 124, and a second anti-reflection layer 126. The photoelectric conversion layer 124 is located between the first anti-reflection layer 122 and the second anti-reflection layer 126. The photoelectric conversion layer 124 in the solar cell substrate 120 is made of, for example, a silicon or an alloy thereof, CdS, CuInGaSe₂ (CIGS), CuInSe₂ (CIS), CdTe, an organic material, or a multi-layer structure stacked by the above materials. The silicon includes single crystal silicon, poly-crystal silicon, and amorphous silicon. The silicon alloy is formed by adding H, F, Cl, Ge, O, C, N, or other atoms into the silicon.

In this embodiment, the photoelectric conversion layer 124 is formed by a first conductive semiconductor layer 127 and a second conductive semiconductor layer 129. The first conductive semiconductor layer 127 is, for example, an N-type semiconductor, and the second conductive semiconductor layer 129 is, for example, a P-type semiconductor. The N-type semiconductor layer 127 is doped with the Group V elements in the periodic table, such as P, As, and Sb. The P-type semiconductor layer 129 is doped with the Group III elements in the periodic table, such as B, Ga, and In. The N-type semiconductor layer 127 contacts the P-type semiconductor layer 129 to form a P-N junction. Upon being irradiated by the sunlight, the junction generates electron-hole pairs, so as to form an electric current in the loop.

The first anti-reflection layer 122 and the second anti-reflection layer 126 are respectively formed on the surfaces of the first conductive semiconductor layer 127 and the second conductive semiconductor layer 129. The first anti-reflection layer 122 and the second anti-reflection layer 126 are made of, for example, SiON or SiNₓ. In an embodiment, the first anti-reflection layer 122 and the second anti-reflection layer 126 are a-SiNₓ:H thin films formed by SiH₄ and NH₃.

The frontside electrode layer 140 is located on the frontside of the solar cell substrate 120, and the frontside electrode layer 140 is formed by, for example, firing the aluminum conductive adhesive, aluminum adhesive, or Ag—Al adhesive. The material of the frontside electrode layer 140 is identical to or different from that of the backside electrode layer.

The structure of the backside electrode layer in this embodiment is applicable for solar cells with various thicknesses, including conventional commercial solar cells with an ordinary thickness of over 200 μm. Since the backside electrode layer in this embodiment can alleviate the warping problem, it is especially suitable for thin solar cells with a thickness below 150 μm or even below 100 μm.

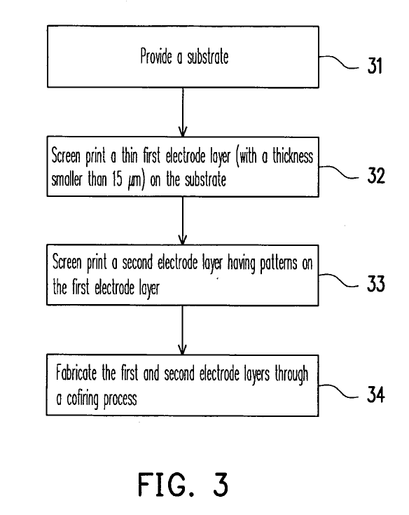

The solar cell employing the backside electrode layer of the present invention has been illustrated above, and similarly, by taking the solar cell as an example, a fabricating method of a backside electrode layer of the present invention will be described below. FIG. 3 is a flow chart of a fabrication process of a backside electrode layer according to an embodiment of the present invention.

Referring to FIGS. 1, 2, and 3, a fabricating method of the backside electrode layer 100 of the present invention is illustrated. First, a solar cell substrate 120 is provided (Step 31). Next, a thin film of aluminum conductive adhesive is fully screen printed on the backside of the solar cell substrate 120 to serve as a first electrode layer 102 (Step 32). Then, a layer of electrode layer material, for example, Ag—Al adhesive, having patterns (grid patterns) is further screen printed on the thin film to serve as a second electrode layer 104 (Step 33). Finally, both the first electrode layer 102 and the second electrode layer 104 are fabricated through a cofiring process (Step 34), and the highest temperature of the cofiring process falls in the range of 750° C. to 800° C. In an embodiment, the screen adopted for screen printing the grid-shaped conductive adhesive to form the second electrode layer 104 is the same as that used for fabricating the frontside electrode layer 140. In another embodiment, the patterns on the second electrode layer 104 are not limited to grid patterns, but may also be hexagonal grid, triangular grid, or other non-full coverage patterns.

As shown in FIG. 2, a bus line 200 is further formed on the backside electrode layer 100, which is provided for connecting the electrodes of the solar cell to external circuits. In an embodiment, the bus line 200 is screen printed after the second electrode layer 104 has been screen printed. Besides the feature that different screens are adopted, the material of the bus line 200 is identical to or different from that of the second electrode layer 104. In another embodiment, the bus line 200 is formed at the same time as the second electrode layer 104 is fabricated. That is, the bus line 200 is designed in the screen for printing the second electrode layer 104, so that both the bus line 200 and the second electrode layer 104 are screen printed on the first electrode layer 102 by the same material. As the frontside electrode layer 140 also has a bus line, and the patterns on the second electrode layer 104 are not fixed, the screen printing process of both the bus line 200 and the second electrode layer 104 may share the screen used by the frontside electrode layer 140 in the screen printing process.

The fabricating method of the backside electrode layer 100 has been illustrated above through the embodiments. The process of sharing the screen and employing a cofiring process may simplify the fabrication process and reduce the cost.

Furthermore, in order to solve the warping problem, the warping degree is measured by, for example, a screw micrometer. First, a test piece is placed on the platform of the screw micrometer, and then the height from the peak point of the test piece to the platform is measured. When the backside electrode fabricated through the method of the present invention is applied to a silicon solar cell with a thickness lower than 140 μm, the warping degree is lower than 0.5 mm. Moreover, when the backside electrode fabricated through the method of the present invention is applied to a silicon solar cell with a thickness lower than 100 μm, a warping degree higher than 1 mm never occurs.

In addition, relevant electronic properties of the backside electrode layer are illustrated below through the embodiments.

### [Test of Backside Electrode Layer]

Two sets of solar cells are prepared for researching the impact of the fabricating method of the backside electrode layer on the conversion efficiency.

### Embodiment 1

A 4×4 inch C—Si substrate with a thickness of 250 μm is adopted to fabricate a solar cell. The P-N junction of the solar cell is fabricated by diffusing phosphorus oxychloride (POCl₃) at 850° C. Then, an anti-reflection layer is respectively formed on a frontside and a backside of a wafer. The anti-reflection layer takes SiH₄ and NH₃ as the precursor, and is fabricated by a capacitive-coupling RF plasma reaction device. Therefore, an a-SiNₓ:H thin film is formed at a reaction temperature of 350° C. Afterward, an aluminum conductive adhesive is fully screen printed on the backside electrode layer to serve as a first electrode layer, and an Ag—Al adhesive having grid patterns is screen printed to serve as a second electrode layer. The first electrode layer has a thickness of 10 μm. The second electrode layer is formed through using the same screen as that used by the frontside electrode layer. Finally, both the first electrode layer and the second electrode layer are cofired at the highest temperature in the range of 750° C. to 800° C. to obtain a thin backside electrode layer.

### Comparative Embodiment 1

A solar cell is fabricated through the same method as that of Embodiment 1, but the difference there-between lies in that: the backside electrode layer is made of an aluminum adhesive and has a thickness of 30 μm.

Then, critical parameters relevant to photoelectric conversion efficiencies of Embodiment 1 and Comparative Embodiment 1 are tested, and the I-V measurement results are shown in Table 1.

TABLE 1

| | Comparative | |
|---|---|---|
| Test Sample | Embodiment 1 | Embodiment 1 |
| Open-circuit Voltage Voc (V) | 0.602 | 0.603 |
| Short-circuit Current | 32.14 | 32.79 |
| Density Jsc (mA/cm²) | | |
| Fill Factor FF (%) | 74.88 | 72.41 |
| Efficiency η (%) | 14.50 | 14.32 |

Table 1 shows that, the test results of Embodiment 1 and Comparative Embodiment 1 are rather close, so that the thin backside electrode layer fabricated through using the aluminum conductive adhesive maintains the energy conversion efficiency of the prior art. Furthermore, as the electric parameters of the solar cells are quite similar, the specifications of the devices connected to the solar cell, for example, a current storage device or an electric energy utilization device, need not be changed. Thus, a solar cell system with similar performances can be achieved simply by altering the fabrication process of the backside electrode layer.

As known from the above test of the backside electrode layer that, the first electrode layer made of the aluminum conductive adhesive combined with the grid-shaped second electrode layer can meet the requirement on the conversion efficiency of the conventional solar cell.

In view of the above, according to the present invention, the first electrode layer with a thickness smaller than 15 μm and the second electrode layer having patterns are formed, so as to reduce the material used by the electrode layer and to lower the fabrication cost. In addition, the thickness of the first electrode layer is reduced from over 30 μm in the prior art to below 15 μm, or even below 10 μm, thereby significantly lowering the material cost.

Furthermore, as the first electrode layer is relatively thin, the stress generated between the first electrode layer and the substrate after the firing process is relatively small. Therefore, the electrode layer remains to be flat, and the warping problem of the electrode layer is effectively alleviated.

Besides, the bus line can be integrated into the screen used by the second electrode layer, and the screen used by the frontside electrode layer can be shared in the screen printing process, so that the fabrication process is simplified and the fabrication cost is reduced.

Moreover, the adopted polyvinyl butyral resin prevents the metal particles from being agglomerated or merged into larger particles during the high-temperature thermal treatment, and the added organic substances are helpful for maintaining the continuity of the electrode layer and avoiding open-circuits or non-uniform electric field.

In addition, the fabricating method of the backside electrode layer provided by the present invention also has the following advantages. For example, the cofiring process of the electrode layers simplifies the fabrication process. The aluminum electrode layer configured in a full coverage manner provides passivation for the substrate, generates a backside electric field, and thus enhances the efficiency of the solar cell. Furthermore, the screen printing technique is mature and has a low cost.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A backside electrode layer, comprising:
a first electrode layer, formed on a substrate; and
a second electrode layer, formed on the first electrode layer, wherein the second electrode layer is formed with patterns.

2. The backside electrode layer according to claim 1, wherein the thickness of the first electrode layer is smaller than 15 μm.

3. The backside electrode layer according to claim 1, wherein the thickness of the first electrode layer is smaller than 10 μm.

4. The backside electrode layer according to claim 1, wherein the patterns on the second electrode layer are grid patterns.

5. The backside electrode layer according to claim 1, further comprising a bus line formed on the first electrode layer.

6. The backside electrode layer according to claim 1, wherein the first electrode layer is formed by firing an aluminum conductive adhesive.

7. The backside electrode layer according to claim 6, wherein the aluminum conductive adhesive comprises:
an aluminum adhesive, 25-30 wt %;
a dispersant, 5-15 wt %;
a bonding agent, 5-15 wt %;
a modifier, 0.005-0.015 wt %; and
a solvent, 20-50 wt %.

8. The backside electrode layer according to claim 1, wherein the dispersant is polyvinyl butyral resin, the bonding agent is ethyl cellulose, the modifier is palmitic acid, and the solvent is α-terpineol.

9. The backside electrode layer according to claim 1, wherein the second electrode layer is formed by firing an Ag—Al adhesive.

10. The backside electrode layer according to claim 1, wherein the substrate is a silicon solar cell substrate.

11. A fabricating method of a backside electrode layer, comprising:
providing a substrate;
screen printing a first electrode layer on the substrate;
screen printing a second electrode layer on the first electrode layer, wherein the second electrode layer is formed with patterns; and
cofiring both the first electrode layer and the second electrode layer.

12. The fabricating method of a backside electrode layer according to claim 11, wherein the thickness of the first electrode layer is smaller than 15 μm.

13. The fabricating method of a backside electrode layer according to claim 11, wherein the thickness of the first electrode layer is smaller than 10 μm.

14. The fabricating method of a backside electrode layer according to claim 11, wherein the patterns on the second electrode layer are grid patterns.

15. The fabricating method of a backside electrode layer according to claim 11, wherein the step of screen printing the second electrode layer on the first electrode layer further comprises screen printing a bus line at the same time.

16. The fabricating method of a backside electrode layer according to claim 11, further comprises screen printing a bus line on the second electrode layer after the step of screen printing the second electrode layer on the first electrode layer.

17. The fabricating method of a backside electrode layer according to claim 11, wherein the first electrode layer is made of an aluminum conductive adhesive.

18. The fabricating method of a backside electrode layer according to claim 17, wherein the aluminum conductive adhesive comprises:
an aluminum adhesive, 25-30 wt %;
a dispersant, 5-15 wt %;
a bonding agent, 5-15 wt %;
a modifier, 0.005-0.015 wt %; and
a solvent, 20-50 wt %.

19. The fabricating method of a backside electrode layer according to claim 18, wherein the dispersant is polyvinyl butyral resin, the bonding agent is ethyl cellulose, the modifier is palmitic acid, and the solvent is α-terpineol.

20. The fabricating method of a backside electrode layer according to claim 11, wherein the second electrode layer is made of an Ag—Al adhesive.

21. The fabricating method of a backside electrode layer according to claim 11, wherein the substrate is a silicon solar cell substrate.
